(19) United States
(12) Patent Application Publication
(10) Pub. No.: US 2003/0054197 A1
(43) Pub. Date: Mar. 20, 2003

(54) Annealing modified interface in organic light emitting devices

(76) Inventor: Raymond Kwong, Plainsboro, NJ (US)

Correspondence Address: KENYON & KENYON, 1500 K STREET, N.W., SUITE 700, WASHINGTON, DC, 20005, US

(21) Appl. No.: 09/956,032

(22) Filed: Sep. 20, 2001

(51) Int. Cl. H05B 33/10; H05B 33/12

(52) U.S. Cl. 428/690; 428/917; 428/212; 427/66; 313/504; 313/506

(57) ABSTRACT

A method of fabricating an organic light emitting device is provided. A substrate having a first conductive layer disposed thereon is obtained. A first small molecule organic layer is deposited over the conductive layer. A second small molecule organic layer is deposited on top of the first small molecule organic layer. The first and second small molecule organic layers are annealed. The annealing is at a temperature such that either (1) there is no significant crystallization of the first and second small molecule organic layers, or (2) the temperature does not exceed the glass transition temperature of either the first or the second small molecule organic layers. A second conductive layer is deposited over the second small molecule organic layer after annealing. A third small molecule organic layer may be deposited either before or after the annealing. In one embodiment, either the first or second small molecule organic layers may be replaced with a polymer layer.

### FIELD OF THE INVENTION

The present invention relates to the field of organic light emitting devices, and more particularly to the fabrication of the organic layers used in such devices.

### BACKGROUND OF THE INVENTION

Organic light emitting devices (OLEDs) are becoming increasingly desirable for a number of reasons. Many of the materials used to make such devices are relatively inexpensive, so organic light emitting devices have the potential for cost advantages over inorganic devices. In addition, the inherent properties of organic materials, such as their flexibility, may make them well suited for particular applications such as fabrication on a flexible substrate. In addition, the wavelength at which an organic emissive layer emits light may generally be readily tuned with appropriate dopants, while it may be more difficult to tune inorganic emissive materials.

OLEDs make use of thin organic films that emit light when voltage is applied across the device. OLEDs are becoming an increasingly popular technology for applications such as flat panel displays, illumination, and backlighting. OLED configurations include double heterostructure, single heterostructure, and single layer, and a wide variety of organic materials may be used to fabricate OLEDs. Several OLED materials and configurations are described in U.S. Pat. No. 5,707,745, which is incorporated herein by reference in its entirety.

One or more transparent electrodes may be useful in an organic opto-electronic device. For example, OLED devices are generally intended to emit light through at least one of the electrodes. For OLEDs from which the light emission is only out of the bottom of the device, that is, only through the substrate side of the device, a transparent anode material, such as indium tin oxide (ITO), may be used as the bottom electrode. Since the top electrode of such a device does not need to be transparent, such a top electrode, which is typically a cathode, may be comprised of a thick and reflective metal layer having a high electrical conductivity. In contrast, for transparent or top-emitting OLEDs, a transparent cathode such as disclosed in U.S. Pat. Nos. 5,703,436 and 5,707,745 may be used. As distinct from a bottom-emitting OLED, a top-emitting OLED is one which may have an opaque and/or reflective substrate, such that light is produced only out of the top of the device and not through the substrate. In addition, a fully transparent OLED that may emit from both the top and the bottom.

As used herein, the term “organic material” includes polymers as wells as small molecule organic materials that may be used to fabricate organic opto-electronic devices. Polymers are organic materials that include a chain of repeating structural units. Small molecule organic materials include all other organic materials. Examples of small molecule organic materials that may be used in OLEDs include:

(1,1′-biphenyl)-4-olato)bis(2-methyl-8-quinolinolato N1,O8)aluminum (BAlq);

copper phthalocyanine (CuPc);

N,N′-diphenyl-N,N′-bis(3-methylphenyl)1-1′biphenyl-4,4′diamine (TPD);

4,4′-bis[N-(1-naphthyl)-N-phenyl-amino]biphenyl (NPD);

aluminum-tris(8-hydroxyquinolate) (Alq₃);

4,4′-N,N′-dicarbazole biphenyl (CBP);

2,9-dimethyl-4,7-diphenyl-1,10-phenanthroline (BCP);

4,4′,4″-tris(3-methylphenylphenylamino)triphenylamine (MTDATA);

poly(3,4-ethylenedioxythiophene) (PEDOT);

tris(2-phenylpyridyl-N, C2′)iridium(III) (Ir(ppy)₃);

bis(2-(4,6-difluorophenyl)pyridyl-N, C2′)iridium(III) picolinate (Firpic); and

iridium (III) bis(benzothienylpyridine) acetylacetonate (BTPIr).

### SUMMARY OF THE INVENTION

A method of fabricating an organic light emitting device is provided. A substrate having a first conductive layer disposed thereon is obtained. A first small molecule organic layer is deposited over the conductive layer. A second small molecule organic layer is deposited on top of the first small molecule organic layer. The first and second small molecule organic layers are annealed. The annealing is at a temperature such that either (1) there is no significant crystallization of the first and second small molecule organic layers, or (2) the temperature does not exceed the glass transition temperature of either the first or the second small molecule organic layers. A second conductive layer is deposited over the second small molecule organic layer after annealing. A third small molecule organic layer may be deposited either before or after the annealing. In one embodiment, either the first or second small molecule organic layers may be replaced with a polymer layer.

### BRIEF DESCRIPTION OF THE DRAWINGS

FIG. 1 shows a double heterostructure organic light emitting device.

FIG. 2 shows plots of current density v. voltage for two green emitting devices, where one of the devices was annealed during fabrication and the other was not.

FIG. 3 shows plots of luminous efficiency (cd/A) v. luminance (cd/m²) for two green emitting devices, where one of the devices was annealed during fabrication and the other was not.

FIG. 4 shows plots of normalized luminance v. time for two green emitting devices, where one of the devices was annealed during fabrication and the other was not.

FIG. 5 shows plots of current density v. voltage for two red emitting devices, where one of the devices was annealed during fabrication and the other was not.

FIG. 6 shows plots of luminous efficiency (cd/A) v. luminance (cd/m²) for two red emitting devices, where one of the devices was annealed during fabrication and the other was not.

### DETAILED DESCRIPTION

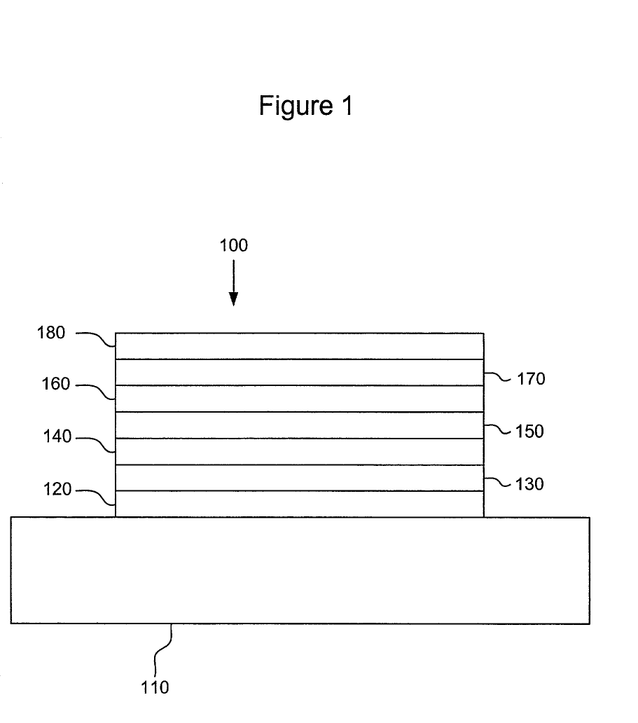

FIG. 1 shows a double heterostructure organic light emitting device 100. Device 100 is fabricated on a substrate 110. Device 100 may include a first conductive layer 120, a hole injection layer 130, a hole transporting layer 140, an emissive layer 150, an electron transporting layer 160, an electron injection layer 170, and a second conductive layer 180. Generally, all of the layers illustrated comprise organic materials except for first conductive layer 120 and second conductive layer 180. In some embodiments, even the conductive layers may include organic materials.

An OLED may include organic layers in addition to those illustrated in FIG. 1, such as an electron blocking layer, a hole blocking layer, or other layers.

An OLED need not include all of the layers illustrated in FIG. 1. For example, a single heterostructure OLED combines the functionality of the emissive layer with one of the transport layers, most frequently but not always the electron transport layer. By way of further example, one or both of the injection layers may be omitted if there is adequate carrier injection without such layers.

In some cases, two or more different organic layers may serve the same function in an OLED. For example, the hole transporting layer may comprise a plurality of sublayers.

Each of the layers of an OLED described above may comprise any material known to the art or that may become known to the art. Preferred materials for many of the layers are described in U.S. Pat. No. 5,707,745, which is incorporated by reference in its entirety.

A method of fabricating an OLED is provided. A substrate is obtained having a first conductive layer disposed thereon. A first organic material is deposited over the first conductive layer. A second organic layer is deposited on top of the first organic layer. After the second organic layer is deposited, an annealing step is performed. A second conductive layer is deposited over the second organic layer after annealing.

Preferably, at least one of the first and second organic layers comprises a small molecule organic material, as distinct from a polymer material. More preferably, both the first and second organic layers comprise small molecule organic materials. While not intending to be limited by any theory of how the invention works, it is believed that annealing two adjacent organic layers allows for some diffusion at the interface, which improves the OLED performance. Two adjacent polymer layers are not believed to diffuse to any significant extent. However, a small molecule organic material may diffuse into an adjacent polymer layer. Also, two adjacent small molecule layers may diffuse into each other.

Exposure to high temperatures may damage the organic layers of an OLED, so the temperature profile of the annealing step may be controlled to limit such damage. It is believed that organic materials as deposited during OLED fabrication are generally amorphous, and that significant crystallization of the organic materials due to exposure to high temperature may adversely affect OLED performance. However, a small degree of crystallization that does not significantly affect the electrical properties of the organic materials may be acceptable. Preferably, there is no crystallization. Such crystallization generally does not occur at temperatures below the glass transition temperature of the organic materials. Crystallization may occur at temperatures above the glass transition temperatures, with the amount of crystallization being dependent on both the temperature and the time of exposure. Accordingly, exposure to temperatures above the glass transition temperature may be acceptable, provided that the time period is short and/or that the temperature does not greatly exceed the glass transition temperature.

As used herein, the term “over” allows for intervening layers. For example, if a second layer is disposed “over” a first layer, there may be a third layer deposited in between the first and second layers. As used herein, the term “on top of” does not allow for intervening layers. For example, if a second layer is deposited “on top of” a first layer, the second layer is in direct physical contact with the first layer, and no layer is deposited in between the first and second layers.

As illustrated in FIG. 1, an OLED may include more than two organic layers. Any number of organic layers may be deposited before the annealing step. However, the annealing is preferably performed with a time/temperature profile such that the annealing does not cause significant crystallization of any of the organic layers deposited prior to annealing. Preferably, the annealing temperature does not exceed the lowest of the glass transition temperatures of the organic materials deposited prior to annealing.

Any number of organic layers may be deposited after annealing. Because these layers are not present for the annealing step, they are not subject to damage from annealing. Accordingly, organic layers that may be damaged by the annealing can still be incorporated into the device by depositing such layers after annealing. For example, an organic layer having a glass transition temperature lower than the annealing temperature may be incorporated into the device by deposition after annealing.

Preferably, all steps are performed in a vacuum without removing the device from vacuum. During deposition, the pressure in the vacuum chamber may reach 10⁻² atmospheres or higher and still be considered a vacuum. Alternatives to performing all steps under vacuum include annealing under an inert gas such as nitrogen.

In one embodiment of the invention, a first organic layer is deposited over a first conductive layer. A second organic layer is deposited on top of the first organic layer. An annealing step is performed. A third organic layer, comprising the same material as the second organic layer, is then deposited on top of the second organic layer. In this embodiment, the second and third organic layers comprise the same material, and form a contiguous layer of that material. However, only the part of the contiguous layer that is deposited prior to annealing, i.e., the second organic layer, is subject to possible damage and/or crystallization during annealing. The part of the contiguous layer that is deposited after annealing, i.e., the third organic layer, is not subject to such damage and/or crystallization. This embodiment is preferred when the annealing step is performed with a time—temperature profile that may cause some crystallization of the second organic layer. For example, the second organic layer may have a lower glass transition temperature than the first organic layer, and it may be desired to anneal at a temperature near the glass transition temperature of the second organic layer. Minor variations in temperature control may result in the temperature exceeding the glass transition temperature of the second organic material for brief periods of time. It may therefore be preferable to expose only a thin second organic layer to the annealing to minimize the volume of material that may experience minor crystallization, and deposit the third organic material after annealing.

OLEDs that emit light primarily via phosphorescence, as opposed to fluorescence, tend to have lower a luminance efficiency and a lower power efficiency at certain current density values of commercial importance. Accordingly, annealing to improve efficiency may be particularly favorable for phosphorescent OLEDs. As used herein, the term “phosphorescence” refers to emission from a triplet excited state and “fluorescence” refers to emission from a singlet excited state.

### EXAMPLES

The following structures were fabricated on a 4″ OLED deposition tool obtained from the Kurt Lesker company of Pittsburgh, Pa. Each structure was fabricated on a patterned ITO coated soda lime glass obtained from Applied Films Corp. of Colorado. The ITO coated substrate was cleaned with solvents and treated with oxygen plasma and UV-ozone prior to the deposition of organic materials.

### Example 1

The following materials were deposited, in sequence: CuPc (100 Å), NPD (150 Å). The CuPc and NPD were annealed at 80 C. for one hour, and the device was then cooled to room temperature. After annealing, the following materials were deposited in sequence: NPD (150 Å), CBP:Ir(ppy)₃ (300 Å), BAlq (100 Å), Alq₃ (400 Å), LiF (10 Å), Al (1000 Å). All steps, including annealing, were performed in situ without removing the device (“device 1”) from vacuum. The Ir(ppy)₃ emissive layer of device 1 emits green light.

### Example 2

The following materials were deposited, in sequence: CuPc (100 Å), NPD (300 Å), CBP:Ir(ppy)₃ (300 Å), BAlq (100 Å), Alq₃ (400 Å), LiF (10 Å), Al (1000 Å). All steps were performed in situ without removing the device from vacuum. The resultant device (“device 2”) has the same layered structure as device 1, except that there was no annealing during the fabrication of device 2. As with device 1, device 2 is designed to emit green light.

### Example 3

A device (“device 3”) was fabricated using the method described in Example 1. However, after depositing NPD (150 Å), 300 Å of CBP:BTPIr was deposited instead of 300 Å of CBP:Ir(ppy)₃. As a result, device 3 is designed to emit red light.

### Example 4

A device (“device” 4) was fabricated using the method described in Example 2. However, after depositing NPD (150 Å), 300 Å of CBP:BTPIr was deposited instead of 300 Å of CBP:Ir(ppy)₃. As with device 3, device 4 is designed to emit red light.

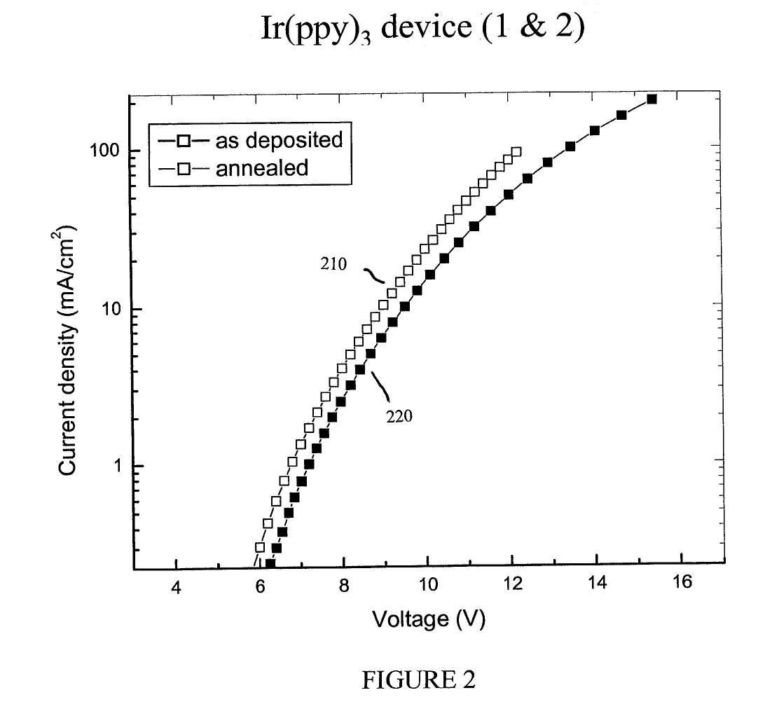

FIG. 2, and specifically plots 210 and 220, shows the current density v. voltage for devices 1 and 2, respectively. As can be seen from the plots, device 1 has a lower drive voltage than device 2. For example, at a current density of 10 mA/cm₂, device 1 has a drive voltage of 9.0 V, while device 2 has a drive voltage of 9.6 V.

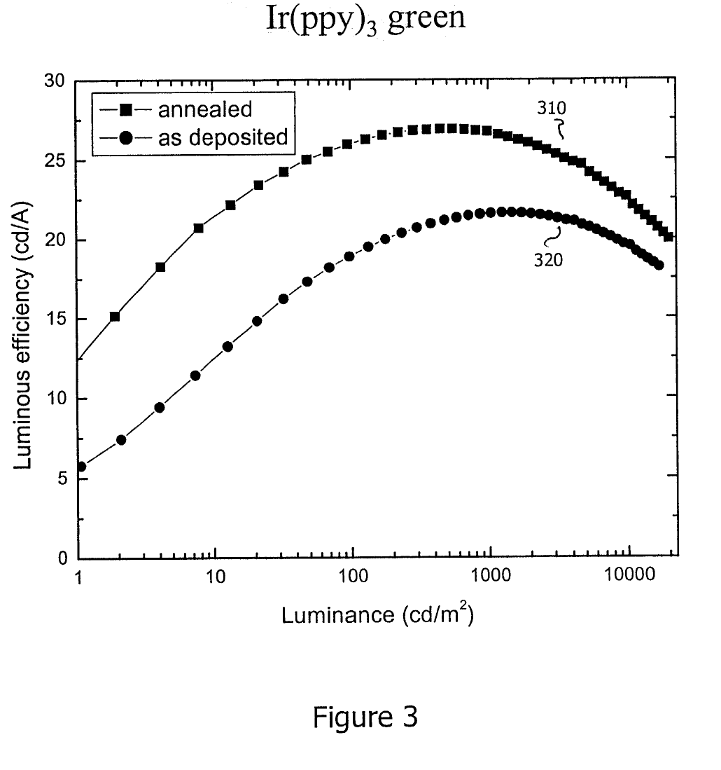

FIG. 3, and specifically plots 310 and 320, shows the luminous efficiency (cd/A) v. luminance (cd/m²) for devices 1 and 2, respectively. As can be seen from the plots, device 1 has a higher luminous efficiency than device 2.

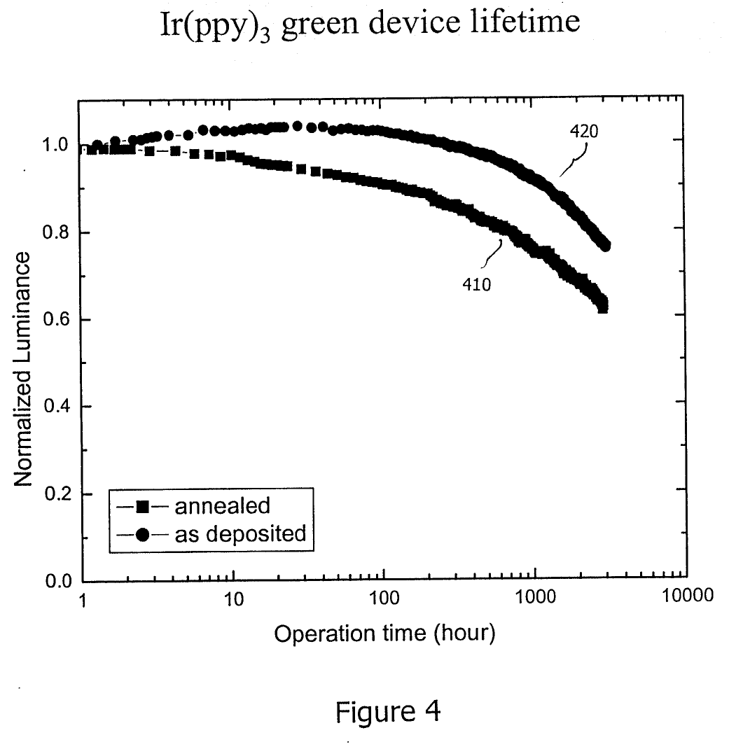

FIG. 4, and specifically plots 410 and 420, shows the normalized luminance v. time for devices 1 and 2, respectively.

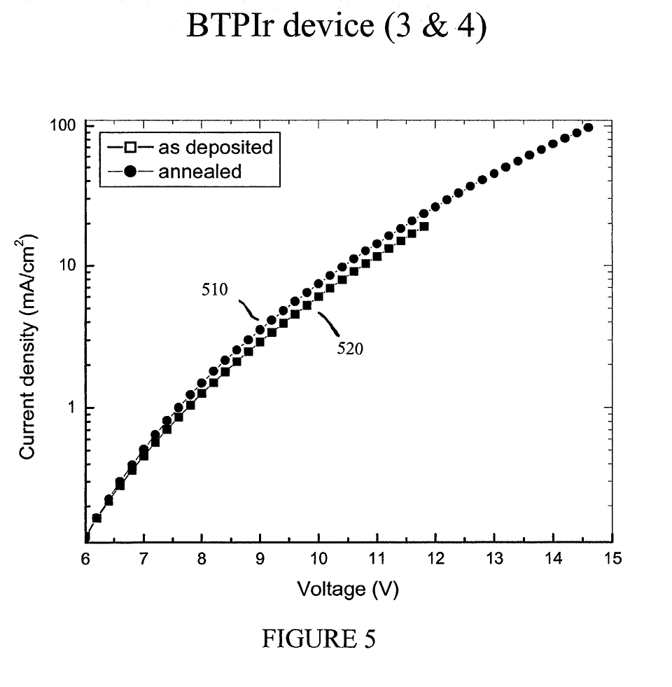

FIG. 5, and specifically plots 510 and 520, shows the current density v. voltage for devices 3 and 4, respectively. As can be seen from the plots, device 3 has a lower drive voltage than device 4.

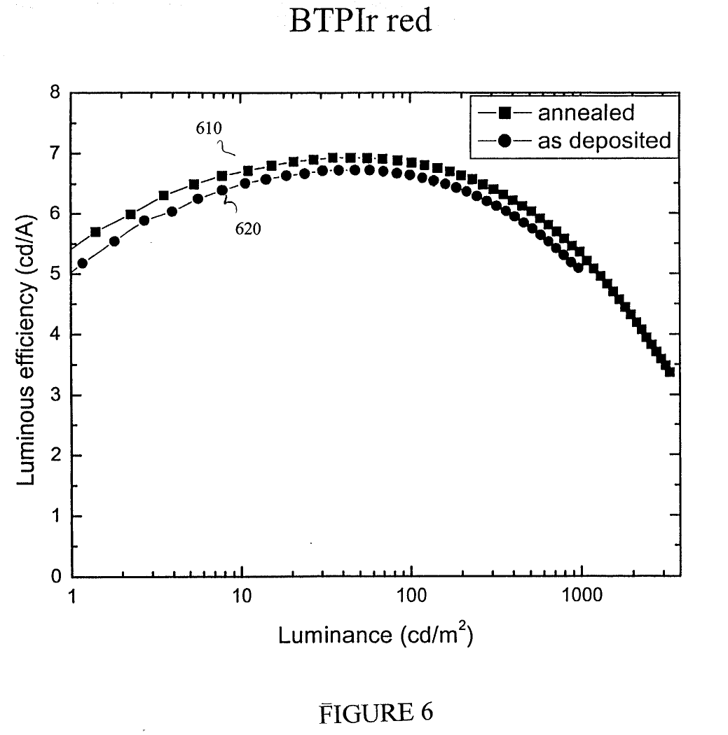

FIG. 6, and specifically plots 610 and 620, shows the luminous efficiency (cd/A) v. luminance (cd/m²) for devices 3 and 4, respectively. As can be seen from the plots, device 3 has a higher luminous efficiency than device 4.

While not intending to be limited by any theory as to how the invention works, it is believed that the annealing of devices 1 and 3 results in a diffused interface between the CuPc and NPD that is not present in devices 2 and 4. This diffused interface may result in a lower drive voltage, and higher luminous efficiency.

While the present invention is described with respect to particular examples and preferred embodiments, it is understood that the present invention is not limited to these examples and embodiments. The present invention as claimed therefore includes variations from the particular examples and preferred embodiments described herein, as will be apparent to one of skill in the art.

What is claimed is:

1. A method of fabricating an organic light emitting device, comprising:
(a) obtaining a substrate having a first conductive layer disposed thereon;
(b) depositing a first small molecule organic layer over the conductive layer;
(c) depositing a second small molecule organic layer on top of the first small molecule organic layer;
(d) annealing the first and second small molecule organic layers such that there is no significant crystallization of the first and second small molecule organic layers;
(e) depositing a second conductive layer over the second small molecule organic layer after annealing.

2. The method of claim 1, wherein the annealing is performed at a temperature that does not exceed the glass transition temperature of either the first small molecule organic layer or the second small molecule organic layer.

3. The method of claim 1, further comprising depositing a third small molecule organic layer on top of the second small molecule organic layer after annealing and before depositing the second conductive layer.

4. The method of claim 3, wherein the third small molecule organic layer has a lower glass transition temperature than the first and second small molecule organic layers.

5. The method of claim 3, wherein the annealing is performed at a temperature higher than the glass transition temperature of the third small molecule organic material.

6. The method of claim 3, wherein the third small molecule organic layer comprises the same material as the second small molecule organic layer.

7. The method of claim 1, further comprising depositing a third small molecule organic layer on top of the second small molecule organic layer before annealing.

8. The method of claim 7, wherein the annealing is performed at a temperature that does not exceed the glass transition temperature of either the first small molecule organic layer, the second small molecule organic layer, or the third small molecule organic layer.

9. The method of claim 1, wherein the first conductive layer includes a conductive metal oxide.

10. The method of claim 1, wherein the annealing is performed in a vacuum.

11. The method of claim 10, wherein the depositing of a first small molecule organic layer, depositing a second small molecule organic material, and annealing are all performed under vacuum and without removing the device from vacuum.

12. The method of claim 1, wherein the first and second small molecule organic layers both comprise hole transporting materials.

13. The method of claim 1, wherein the first and second small molecule organic layers both comprise electron transporting materials.

14. The method of claim 1, wherein the first small molecule organic layer comprises a hole transporting layer and the second small molecule organic layer comprises an emissive layer.

15. The method of claim 1, wherein the organic light emitting device is a phosphorescent organic light emitting device.

16. A method of fabricating an organic light emitting device, comprising:
(a) obtaining a substrate having a first conductive layer disposed thereon;
(b) depositing a first small molecule organic layer over the conductive layer;
(c) depositing a second small molecule organic layer over the first small molecule organic layer;
(d) annealing the first and second small molecule organic layers at a temperature that does not exceed the glass transition temperature of either the first or the second small molecule organic layers;
(e) depositing a second conductive layer over the second small molecule organic layer after annealing.

17. The method of claim 16, further comprising depositing a third small molecule organic layer on top of the second small molecule organic layer after annealing and before depositing the second conductive layer.

18. The method of claim 17, wherein the third small molecule organic layer has a lower glass transition temperature than the first and second small molecule organic layers.

19. The method of claim 17, wherein the annealing is performed at a temperature higher than the glass transition temperature of the third small molecule organic material.

20. The method of claim 17, wherein the third small molecule organic layer comprises the same material as the second small molecule organic layer.

21. The method of claim 16, further comprising depositing a third small molecule organic layer on top of the second small molecule organic layer before annealing.

22. The method of claim 21, wherein the annealing is performed at a temperature that does not exceed the glass transition temperature of either the first small molecule organic layer, the second small molecule organic layer, or the third small molecule organic layer.

23. The method of claim 16, wherein the organic light emitting device is a phosphorescent organic light emitting device.

24. A method of fabricating an organic light emitting device, comprising:
(a) obtaining a substrate having a first conductive layer disposed thereon;
(b) depositing a first organic layer over the conductive layer;
(c) depositing a second organic layer over the first organic layer;
(d) annealing the first and second organic layers such that there is no significant crystallization of the organic layers;
(e) depositing a second conductive layer over the second organic layer after annealing; wherein at least one of the first and second organic layers comprise a small molecule organic material.

25. The method of claim 24, wherein at least one of the first and second organic layers comprises a polymer

26. A device fabricated by the process of:
(a) obtaining a substrate having a first conductive layer disposed thereon;
(b) depositing a first small molecule organic layer over the conductive layer;
(c) depositing a second small molecule organic layer on top of the first small molecule organic layer;
(d) annealing the first and second small molecule organic layers such that there is no significant crystallization of the first and second small molecule organic layers;
(e) depositing a second conductive layer over the second small molecule organic layer after annealing.

27. The device of claim 26, wherein the annealing is performed at a temperature that does not exceed the glass transition temperature of either the first small molecule organic layer or the second small molecule organic layer.

28. The device of claim 26, wherein the process further comprises depositing a third small molecule organic layer on top of the second small molecule organic layer after annealing and before depositing the second conductive layer.

29. The device of claim 28, wherein the third small molecule organic layer has a lower glass transition temperature than the first and second small molecule organic layers.

30. The device of claim 28, wherein the annealing is performed at a temperature higher than the glass transition temperature of the third small molecule organic material.

31. The device of claim 28, wherein the third small molecule organic layer comprises the same material as the second small molecule organic layer.

32. The device of claim 26, wherein the process further comprises depositing a third small molecule organic layer on top of the second small molecule organic layer before annealing.

33. The device of claim 32, wherein the annealing is performed at a temperature that does not exceed the glass transition temperature of either the first small molecule organic layer, the second small molecule organic layer, or the third small molecule organic layer.

34. The device of claim 26, wherein the first conductive layer includes a conductive metal oxide.

35. The device of claim 26, wherein the annealing is performed in a vacuum.

36. The device of claim 35, wherein the depositing of a first small molecule organic layer, depositing a second small molecule organic material, and annealing are all performed under vacuum and without removing the device from vacuum.

37. The device of claim 26, wherein the first and second small molecule organic layers both comprise hole transporting materials.

38. The device of claim 26, wherein the first and second small molecule organic layers both comprise electron transporting materials.

39. The device of claim 26, wherein the first small molecule organic layer comprises a hole transporting layer and the second small molecule organic layer comprises an emissive layer.

40. The device of claim 26, wherein the organic light emitting device is a phosphorescent organic light emitting device.

41. A method of fabricating an organic light emitting device, comprising:
(a) obtaining a substrate having a first conductive layer disposed thereon;
(b) depositing a first small molecule organic layer over the conductive layer;
(c) depositing a second small molecule organic layer over the first small molecule organic layer;
(d) annealing the first and second small molecule organic layers at a temperature that does not exceed the glass transition temperature of either the first or the second small molecule organic layers;
(e) depositing a second conductive layer over the second small molecule organic layer after annealing.

42. The device of claim 41, wherein the process further comprises depositing a third small molecule organic layer on top of the second small molecule organic layer after annealing and before depositing the second conductive layer.

43. The device of claim 42, wherein the third small molecule organic layer has a lower glass transition temperature than the first and second small molecule organic layers.

44. The device of claim 42, wherein the annealing is performed at a temperature higher than the glass transition temperature of the third small molecule organic material.

45. The device of claim 42, wherein the third small molecule organic layer comprises the same material as the second small molecule organic layer.

46. The device of claim 41, wherein the process further comprises depositing a third small molecule organic layer on top of the second small molecule organic layer before annealing.

47. The device of claim 46, wherein the annealing is performed at a temperature that does not exceed the glass transition temperature of either the first small molecule organic layer, the second small molecule organic layer, or the third small molecule organic layer.

48. The device of claim 41, wherein the organic light emitting device is a phosphorescent organic light emitting device.

49. A method of fabricating an organic light emitting device, comprising:
(a) obtaining a substrate having a first conductive layer disposed thereon;
(b) depositing a first organic layer over the conductive layer;
(c) depositing a second organic layer over the first organic layer;
(d) annealing the first and second organic layers such that there is no significant crystallization of the organic layers;
(e) depositing a second conductive layer over the second organic layer after annealing; wherein at least one of the first and second organic layers comprise a small molecule organic material.

50. The device of claim 49, wherein at least one of the first and second organic layers comprises a polymer
